(19) United States
(12) Patent Application Publication
(10) Pub. No.: US 2006/0151881 A1
(43) Pub. Date: Jul. 13, 2006

(54) Semiconductor device and method of manufacture thereof

(75) Inventor: Masaki Yamada, Yokohama-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/083,338

(22) Filed: Mar. 18, 2005

(30) Foreign Application Priority Data
Jan. 13, 2005 (JP) 2005-006433

(51) Int. Cl. H01L 23/52; H01L 23/48; H01L 29/40

(52) U.S. Cl. 257/758

(57) ABSTRACT

A semiconductor device comprises a semiconductor element formed in a semiconductor substrate, a plurality of insulating films stacked on the semiconductor substrate, a plurality of wiring layers each of which is formed in a respective one of the insulating films, and a barrier metal formed to continuously cover each of the wiring layers on the top and on both sides.

### CROSS-REFERENCE TO RELATED APPLICATIONS

This application is based upon and claims the benefit of priority from prior Japanese Patent Application No. 2005-006433, filed Jan. 13, 2005, the entire contents of which are incorporated herein by reference.

### BACKGROUND OF THE INVENTION

1. Field of the Invention

The present invention relates to multiple levels of wiring layers using, by way of example, a low-dielectric-constant (low-k) insulating film, and more particularly to a semiconductor device in which two or more levels of wiring layers are stacked, and a method of manufacture thereof.

2. Description of the Related Art

In recent years, large-scale integrated circuits (LSIs) in which a large number of transistors, resistors and so on which comprise an electric circuit are integrated onto a single chip have been used extensively in computers and communication devices. For this reason, the overall performance of equipment depends solely on the LSIs used. The performance of LSIs can be improved by increasing their packing density, namely, by scaling down the dimensions of devices.

However, scaling down the dimensions of devices leads to an increase in signal delay resulting from capacitive coupling between wirings, which impedes high-speed operation of the devices. To reduce the coupling capacitance between wirings, therefore, insulating materials of low dielectric constant have come into use. Another method to reduce the capacitance between wirings is to reduce the thicknesses of adjacent wiring layers so that the area of opposed sides of the wiring layers is reduced. However, the use of materials of low dielectric constant, which has been recommended as a method to reduce the capacitance between wirings, and the reduction of the thicknesses of wiring layers have the following problems:

The low-dielectric-constant requirements of insulating materials cannot be met sufficiently by merely changing the insulating materials. That is, the reduction in dielectric constant is attained by lowering the relative dielectric constants of the insulating films themselves and further lowering their densities. In that case, the mechanical strength and adhesion of the insulating films which have their dielectric constants lowered will be reduced, thus considerably lowering the resistance to mechanical stress and thermal stress in a deposition process and heat treatment. In forming multiple levels of wiring layers in particular, the deposition process, heat treatment and chemical mechanical polishing (CMP) process are carried out repeatedly, thus considerably lowering the resistance of insulating materials to mechanical and thermal stress.

When wiring layers are made thin or when fine wiring layers are stacked one on top of the other, the thermal stress cycle in deposition processes, heat treatment, etc., causes or threatens a degradation in the reliability of the wirings such as stress migration.

Thus, for multiple levels of wiring layers in LSIs which have made advances in performance and packing density, how to suppress the mechanical and thermal stresses of insulating films of low dielectric constant and fine wirings is important.

In order to improve the structural quality of multiple levels of wiring layers and reduce the manufacturing time, a method of separately manufacturing each region of multiple levels of wiring layers has been proposed (see, for example, Jpn. Pat. Appln. KOKAI Publication No. 2004-235454).

However, with this manufacturing method, it is difficult to sufficiently suppress the mechanical and thermal stresses of insulating films of low-k material. Demand has therefore increased for the development of a semiconductor device adapted to the suppression of the mechanical and thermal stresses of lower levels of wiring layers close to semiconductor elements and insulating films of low dielectric constant and a method of manufacture thereof.

### BRIEF SUMMARY OF THE INVENTION

According to a first aspect of the present invention, there is provided a semiconductor device comprising: a semiconductor element formed in a semiconductor substrate; a plurality of insulating films stacked on the semiconductor substrate; a plurality of wiring layers each of which is formed in a respective one of the insulating films; and a barrier metal formed to continuously cover each of the wiring layers on the top and on both sides.

According to a second aspect of the present invention, there is provided a semiconductor device comprising: a semiconductor element formed in a semiconductor substrate; a plurality of insulating films stacked on the semiconductor substrate; a plurality of wiring layers each of which is formed in a respective one of the insulating films; a plurality of plugs each of which is formed in a respective one of the insulating films to connect the wiring layer formed in the corresponding insulating film and the wiring layer formed in another insulating film; and a barrier metal formed to continuously cover the corresponding wiring layer and the plug on the corresponding wiring layer on the top and on both sides.

According to a third aspect of the present invention, there is provided a method of manufacturing a semiconductor device comprising: forming an upper wiring layer on the surface of a first semiconductor substrate; forming at least one lower wiring layer on the upper wiring layer; and bonding the lower wiring layer formed on the first semiconductor substrate to a second semiconductor substrate including a semiconductor element.

According to a fourth aspect of the present invention, there is provided a method of manufacturing a semiconductor device comprising: forming a first insulating film having a first dielectric constant on the surface of a first semiconductor substrate; forming an upper-level wiring layer in the first insulating film; forming a second insulating film having a second dielectric constant lower than the first dielectric constant on the first insulating film; forming at least one lower-level wiring layer in the second insulating film; and bonding the lower-level wiring layer formed on the first semiconductor substrate to a second semiconductor substrate including a semiconductor element.

According to a fifth aspect of the present invention, there is provided a method of manufacturing a semiconductor device comprising: forming a first insulating film having a first dielectric constant over the surface of a first semiconductor substrate; forming an upper-level wiring layer in the first insulating film; forming a second insulating film having a second dielectric constant lower than the first dielectric constant on the surface of a second semiconductor substrate; forming at least one lower-level wiring layer in the second insulating film; bonding the lower-level wiring layer formed on the second semiconductor substrate to a third semiconductor substrate including a semiconductor element; and bonding the first semiconductor substrate having the first insulating film and the upper-level wiring layer to the second insulating film after removal of the second semiconductor substrate.

### BRIEF DESCRIPTION OF THE SEVERAL VIEWS OF THE DRAWING

FIG. 1 is a sectional view of a semiconductor device according to a first embodiment of the present invention;

FIGS. 2 through 6 are sectional views, in the order of steps of manufacture, of the semiconductor device shown in FIG. 1;

FIG. 7 is a sectional view of a semiconductor device according to a second embodiment of the present invention;

FIG. 8 is a sectional view illustrating the step of manufacturing a portion of the semiconductor device shown in FIG. 7;

FIG. 9 is a sectional view illustrating the step of manufacturing another portion of the semiconductor device shown in FIG. 7;

FIG. 10 is a sectional view of a semiconductor device manufactured using a dual damascene process according to a third embodiment of the present invention; and

FIG. 11 is a sectional view of a semiconductor device manufactured using a conventional dual damascene process.

### DETAILED DESCRIPTION OF THE INVENTION

The embodiments of the invention will be described below in detail with reference to the accompanying drawings.

### First Embodiment

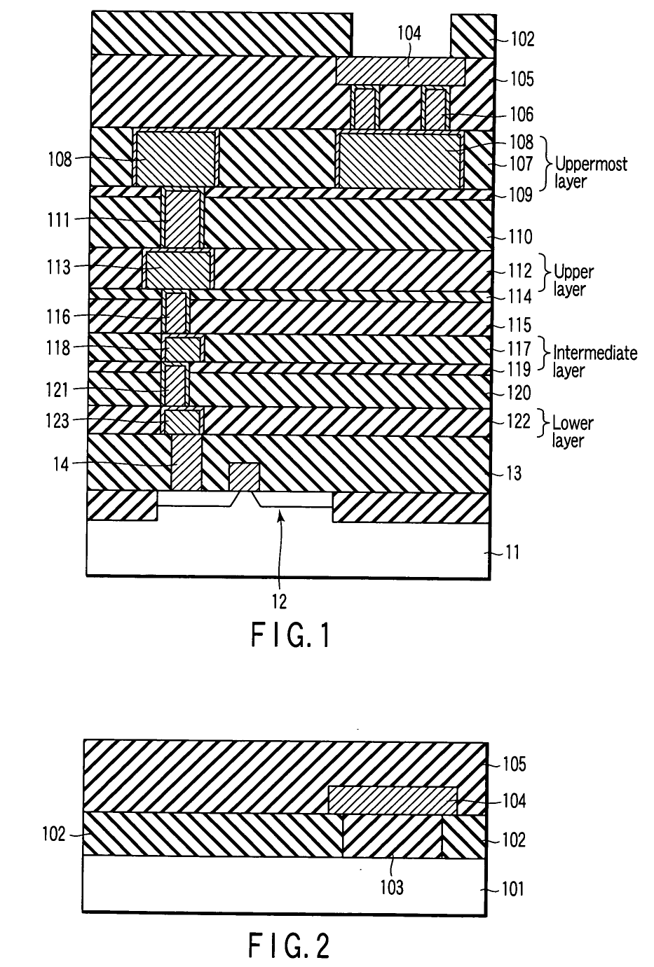

FIG. 1 shows the structure of a semiconductor device according to a first embodiment of the present invention. This semiconductor device is formed, for example, by bonding a semiconductor device formed on a semiconductor substrate and multilevel wiring layers formed on another semiconductor substrate. For example, a semiconductor substrate 11 has a MOSFET 12 formed in it and is formed with an insulating film 13 on top which covers the MOSFET 12. A contact 14 is formed in the insulating film 13 which is connected to, for example, the source of the MOSFET 12.

Another semiconductor substrate (not shown) is formed with, on its top, a first interlayer insulating film 102, a second interlayer insulating film 105, a third interlayer insulating film 107, a fourth interlayer insulating film 110, a fifth interlayer insulating film 112, a sixth interlayer insulating film 115, a seventh interlayer insulating film 117, an eighth interlayer insulating film 120, a ninth interlayer insulating film 122, anti-diffusion films 109, 114 and 119, a bonding electrode 104, a uppermost-level wiring layer 108, an upper-level wiring layer 113, an intermediate-level wiring layer 118, a lower-level wiring layer 123, connect plugs 106, and via plugs 111, 116 and 121. The first, second, third and fourth interlayer insulating films 102, 105, 107 and 110 each consist of, for example, a silicon oxide film (SiO₂), whereas the fifth, sixth, seventh, eighth and ninth interlayer insulating films 112, 115, 117, 120 and 122 each consist of a low-k film, for example, an SiOC film (carbon-containing silicon oxide film). These interlayer insulating films, wiring layers and via plugs are formed consecutively on the semiconductor substrate not shown starting with the first interlayer insulating film 102 closest to the substrate. That is, the multilevel wiring layers are formed consecutively on the semiconductor substrate not shown starting with the uppermost-level wiring layer 108, i.e., in reverse order to that in normal manufacturing processes.

The structure shown in FIG. 1 is obtained by bonding the ninth interlayer insulating film 122 and the lower-level wiring layer 123 of the second substrate to the surface of the insulating film 13 and the contact 14 of the first substrate.

By forming the upper-level insulating films, wiring layers and via plugs before the lower-level insulating films, wiring layers and via plugs as described above, it becomes possible to relax mechanical and thermal stresses on the lower-level insulating films consisting of low-k films and the lower-level wiring layers which are thinner and narrower than the upper-level wiring layers.

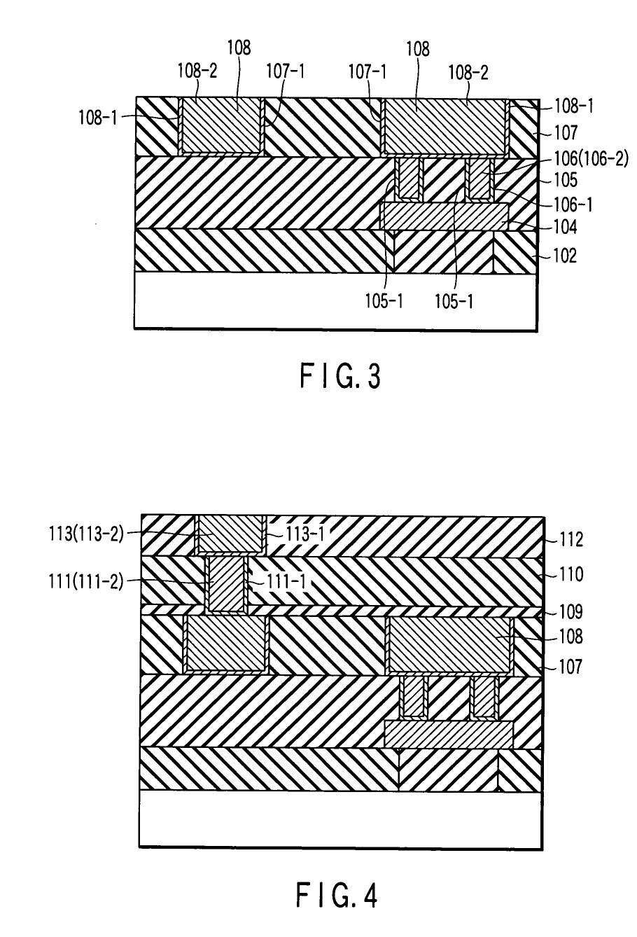

Reference is now made to FIGS. 2 through 6 to describe a method of manufacturing the semiconductor device according to the first embodiment. FIGS. 2 through 6 illustrate the process of forming the multilevel wiring layers shown in FIG. 1 on the second substrate. In this example, Cu wiring layers and plugs are formed using a single damascene process.

The method of fabricating the semiconductor device in-the first substrate 11 shown in FIG. 1 remains unchanged from the conventional method and hence a description thereof is omitted.

First, as shown in FIG. 2, a first interlayer insulating film 102 is deposited on the surface of a semiconductor substrate 101. After that, an opening is formed in the first interlayer insulating film and a sacrificial film 103 is formed in that opening. Subsequently, an Al film 104 as a bonding electrode metal is formed on the sacrificial film 103 and then processed into the shape of an electrode. Then, a second interlayer insulating film 105 consisting of, for example, SiO₂, is deposited and planarized.

Next, as shown in FIG. 3, two or more openings 105-1 are formed in the second interlayer insulating film 105 to expose the bonding electrode metal 104. After that, a barrier metal 106-1, in the form of, for example, tantalum, is formed on the second interlayer insulating film 105 and the bottoms and sidewalls of the respective openings 105-1, and then a Cu film 106-2 is formed on the barrier metal 106-1. The barrier metal 106-1 prevents the diffusion of Cu. Next, the second interlayer insulating film 105 is subjected to a planarization step by, for example, chemical mechanical polishing (CMP) to remove the Cu film 106-2 and the barrier metal 106-1 on its top. As a result, plugs 106 are formed in the openings 105-1. The plugs 106 are each composed of the barrier metal 106-1 formed on the bottoms and sidewalls of the openings 105-1 and the Cu film 106-2.

Next, a third interlayer insulating film 107, in the form of, say, SiO₂, is deposited on the entire surface of the second interlayer insulating film 105. Using a layer of resist not shown as a mask, trenches 107-1 for the uppermost wiring layers are formed in the third interlayer insulating film 107 by means of reactive ion etching (RIE). After that, a barrier metal 108-1, consisting of, for example, tantalum, is formed on the third interlayer insulating film 107 and the bottoms and sidewalls of the respective trenches 107-1 and a Cu film 108-2 is then formed on the barrier metal 108-1. The third interlayer insulating film 107 is then subjected to a planarization step by, for example, CMP to remove the Cu film 108-2 and the barrier metal 108-1 on its top, so that uppermost-level wiring layers 108 are formed in the trenches 107-1. The uppermost-level wiring layers 108 are each composed of the barrier metal 108-1 formed on the bottoms and sidewalls of the trenches 107-1 and the Cu film 108-2. The uppermost-level wiring layers 108 are global wiring layers, such as power supply, data bus and clock lines, which realize communication of electrical signals among the functional circuit blocks within the entire chip.

Likewise, the other wiring layers and contacts are formed consecutively. In the description which follows, the detailed steps of manufacturing barrier metals, wiring layers and contacts are omitted.

Next, as shown in FIG. 4, an anti-diffusion film 109, which prevents the diffusion of Cu in the uppermost-level wiring layers 108 and is composed of, for example, SiC, is deposited on the entire surface of the uppermost-level wiring layers 108 and the third interlayer insulating film 107. After that, a fourth interlayer insulating film 110, consisting of, for example, SiO₂, is deposited on the entire surface of the anti-diffusion film. An opening is then formed in the fourth interlayer insulating film 110 and the anti-diffusion film 109. After that, a via plug 111 that connects the uppermost-level wiring layer 108 and an upper-level wiring layer is formed in that opening. The via plug 111 is composed of a Cu film 111-2 whose bottom and side are continuously covered with a barrier metal 111-1.

Next, a fifth interlayer insulating film 112 is deposited on the entire surface of the via plug 111 and the fourth interlayer insulating film 110. The fifth interlayer insulating film 112 is a low-k film consisting of, for example, vacancy-free SiOC. After that, a trench for an upper-level wiring layer is formed in the fifth interlayer insulating film by RIE using a layer of resist as a mask. An upper-level wiring layer 113 is then formed in that trench. This upper-level wiring layer is composed of a Cu film 113-2 whose bottom and side are continuously covered with a barrier metal 113-1. The upper-level wiring layer 113 is a semi-global wiring layer that has the function of transmission and distribution of control signals, clocks, or power by way of example.

Next, as shown in FIG. 5, an anti-diffusion film 114, which prevents Cu diffusion and consists of, for example, SiC, is deposited on the entire surface of the upper-level wiring layer 113 and the fifth interlayer insulating film 112. A sixth interlayer insulating film 115 is deposited on the entire surface of the anti-diffusion film 114. The sixth interlayer insulating film 115 is a low-k film consisting of, for example, vacancy-free SiOC. An opening is then formed in the sixth interlayer insulating film 115 and the anti-diffusion film 114. A via plug 116 is formed in that opening. The via plug 116 is composed of a Cu film 116-2 whose bottom and side are continuously covered with a barrier metal 116-1.

Next, a seventh interlayer insulating film 117 is deposited on the entire surface of the via plug 116 and the sixth interlayer insulating film 115. The seventh interlayer insulating film 117 is a low-k film consisting of, for example, SiOC with a large vacancy rate. After that, a trench is formed in the seventh interlayer insulating film 117 by RIE using a layer of resist as a mask. An intermediate-level wiring layer 118 is then formed in that trench. This intermediate-level wiring layer 118 is composed of a Cu film 118-2 whose bottom and side are continuously covered on the with a barrier metal 118-1. The intermediate-level wiring layer 118 is, by way of example, an intermediate wiring layer adapted for connection within a unit circuit block or between adjacent circuit blocks.

Next, as shown in FIG. 6, an anti-diffusion film 119, which prevents Cu diffusion and consists of, for example, SiC, is deposited on the entire surface of the intermediate wiring layer 118 and the seventh interlayer insulating film 117. An eighth interlayer insulating film 120 is deposited on the entire surface of the anti-diffusion film 119. The eighth interlayer insulating film 120 is a low-k film consisting of, for example, SiOC with a large vacancy rate. An opening is then formed in the eighth interlayer insulating film 120 and the anti-diffusion film 119. A via plug 121 is formed in that opening. The via plug 121 is composed of a Cu film 121-2 whose bottom and side are continuously covered with a barrier metal 121-1.

Next, a ninth interlayer insulating film 122 is deposited on the entire surface of the via plug 121 and the eighth interlayer insulating film 120. The ninth interlayer insulating film 122 is a low-k film consisting of, for example, SiOC with a large vacancy rate. After that, a trench is formed in the ninth interlayer insulating film 122 by RIE using a layer of resist as a mask. A low-level wiring layer 123 is then formed in that trench. This low-level wiring layer 123 is composed of a Cu film 123-2 whose bottom and side are continuously covered with a barrier metal 123-1. The low-level wiring layer 123 is, by way of example, a local wiring layer that connects transistors or memory cells. After that, the ninth interlayer insulating film 122 and the lower-level wiring layer 123 are mirror surface finished.

Next, as shown in FIG. 1, the semiconductor substrate 101 formed with the multilevel wiring layers fabricated as shown in FIGS. 2 through 6 is bonded to the semiconductor substrate 11 formed with transistors. That is, the semiconductor substrate 101 is bonded to the semiconductor substrate 11 so that the lower-level wiring layer metal 123 formed on the substrate 101 comes into contact with the contact electrode 14 on the substrate 11.

After that, the substrate 101 and the sacrificial film 103 are stripped off consecutively. Thereby, the semiconductor device having the bonding electrode 104 exposed as shown in FIG. 1 is obtained.

According to the first embodiment, the upper-, intermediate- and lower-level insulating films, wiring layers and via plugs are formed in this order, which is the reverse of that in the conventional process. In the case of the conventional manufacturing process, low-k films formed earlier will be subjected to mechanical and thermal stresses respectively caused by CMP and heat treatment, which are associated with the formation of interlayer insulating films and wiring layers formed later. According to the first embodiment, however, the fifth through ninth low-k interlayer insulating films 112 through 122 and the intermediate- and lower-level wiring layers 118 and 123, which are thinner and narrower than the upper-level wiring layers, are formed later than the first through fourth SiO₂ interlayer insulating films 102 through 110 and the upper-level wiring layers. Therefore, mechanical and thermal stresses on the fifth through ninth low-k interlayer insulating films 112 through 122 formed of low-k films and the narrow intermediate- and lower-level wiring layers 118 and 123 can be relaxed.

### Second Embodiment

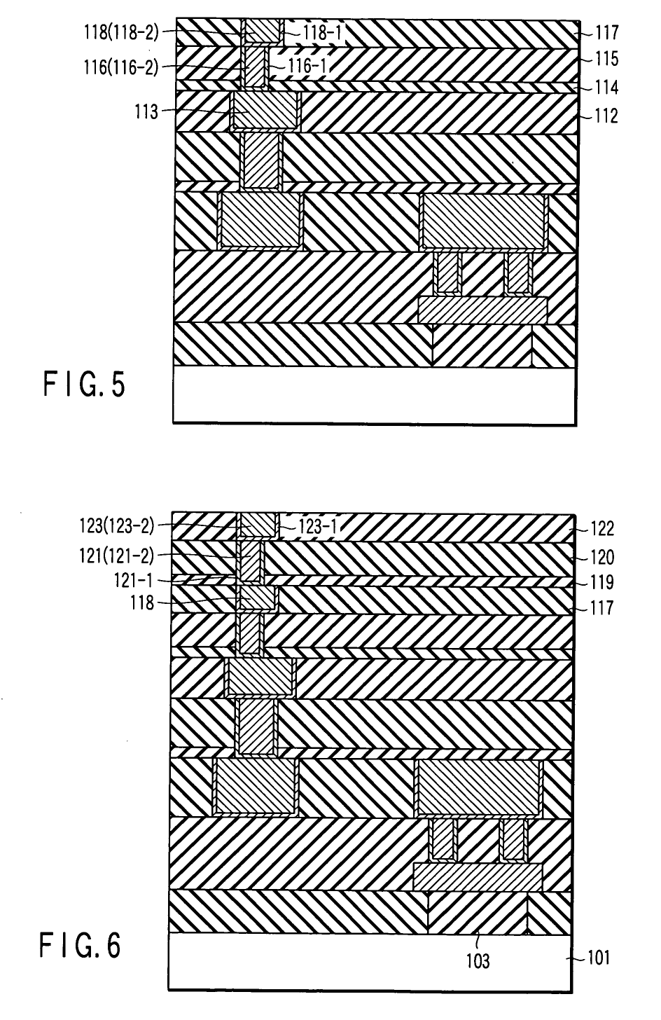

FIGS. 7, 8 and 9 show a second embodiment of the present invention.

The first embodiment has been described in terms of four levels of wiring layers comprising lower-, intermediate-, upper- and uppermost-level wiring layers fabricated by the single damascene process. It is also possible to apply the aforementioned manufacturing method to such a semiconductor device as shown in FIG. 7 which has a total of eleven levels of wiring layers comprising two uppermost levels of wiring layers (108a and 108b), four upper levels of wiring layers (113a, 113b, 113c and 113d), four intermediate levels of wiring layers (118a, 118b, 118c and 118d), and one lower level of wiring layer (123), or a semiconductor device having more levels of wiring layers.

In fabricating a semiconductor device having such multiple levels of wiring layers, it is also possible to form low-k film-containing wiring layers and SiO₂-film-containing wiring layers on separate semiconductor substrates and bond these semiconductor substrates.

In general, the low-k film yield is lower than that of the SiO₂ film. When these films are formed together, the low-k film may peel off and adhere to the wafer substrate, producing a scratch. That is, the low-k film yield affects the overall product yield.

In the second embodiment, therefore, the lower and intermediate wiring layers containing low-k films and the upper and uppermost wiring layers containing SiO₂ films of the semiconductor device shown in FIG. 7 are formed separately.

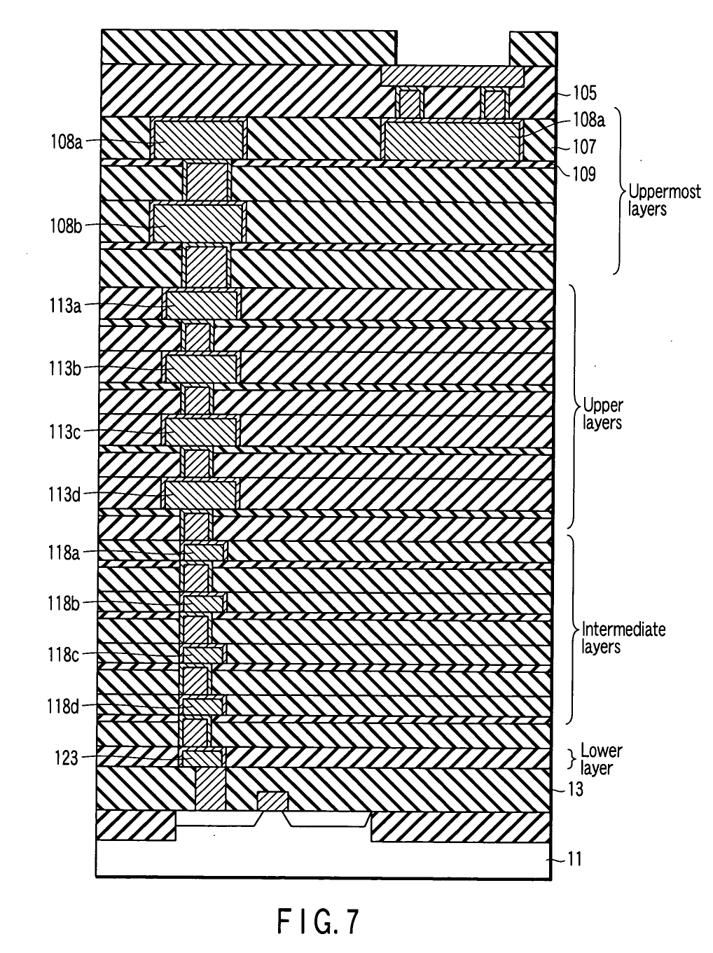

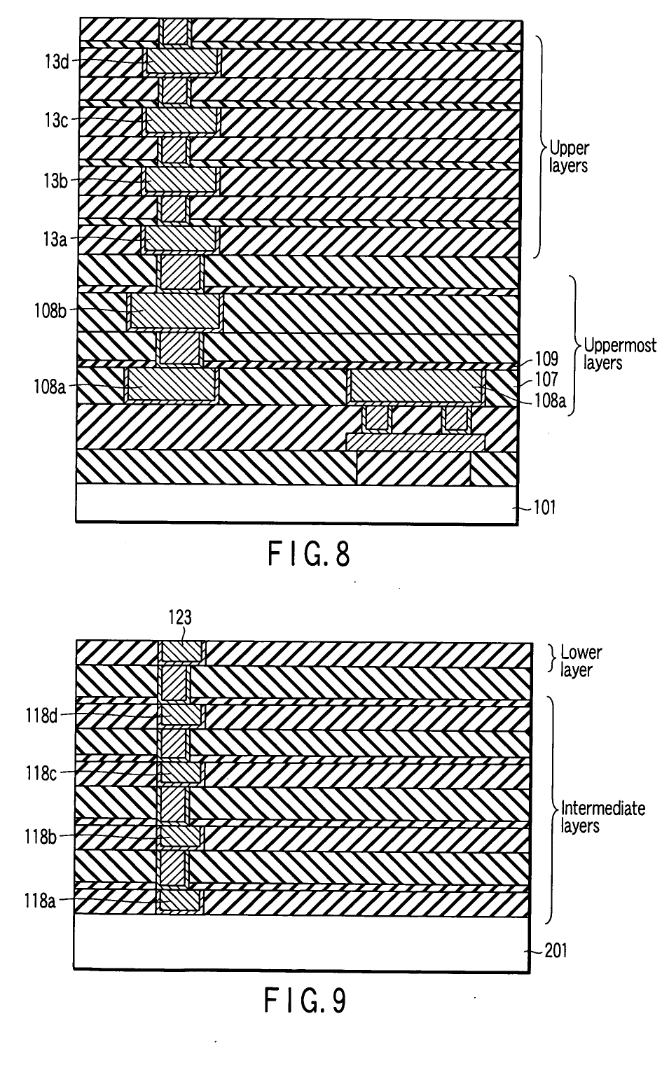

That is, as shown in FIG. 8, the uppermost wiring layers and the upper wiring layers shown in FIG. 7 are formed on a semiconductor substrate 101 as in the case of the first embodiment. On the other hand, as shown in FIG. 9 the intermediate wiring layers and the lower wiring layer shown in FIG. 7 are formed consecutively on a semiconductor substrate 201. The lower wiring layer thus formed on the semiconductor substrate 201 is bonded to a semiconductor substrate 11 formed with MOSFETs, as shown in FIG. 7. After that, the semiconductor substrate 201 is stripped off and then the upper wiring layers formed on the semiconductor substrate 101 shown in FIG. 8 are bonded to the intermediate wiring layer. After that, the semiconductor substrate 101 is stripped off and then the sacrificial film is removed, whereby the semiconductor substrate shown in FIG. 7 is obtained.

According to the second embodiment, the low-k-film-containing lower and intermediate wiring layers and the SiO₂-film-containing upper and uppermost wiring layers are fabricated on separate semiconductor substrates and then bonded consecutively to the semiconductor substrate 11 formed with MOSFETs. Therefore, the low-k-film-containing lower and intermediate wiring layers, after having been fabricated, can be screened to segregate quality products. The quality lower and intermediate wiring layers can be sandwiched between the MOSFET-formed semiconductor substrate 11 and the SiO₂-film-containing wiring layers to thereby produce finished products. Therefore, the effect of the low-k film yield on the overall product yield can be eliminated.

### Third Embodiment

Although the first and second embodiments have been described in terms of the manufacturing method using the single damascene process to form wiring layers and plugs separately, this is not restrictive. It is also possible to use a dual damascene process.

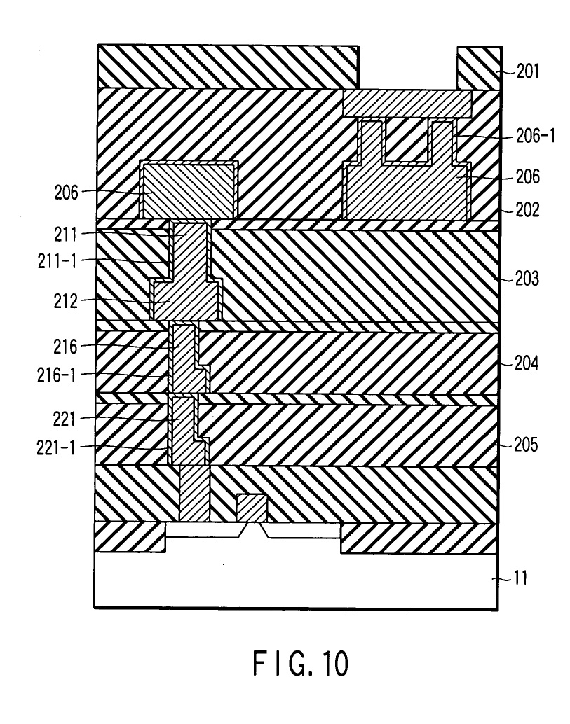

FIG. 10 shows a semiconductor device according to a third embodiment of the present invention. This semiconductor device is fabricated by bonding multilevel wiring layers formed using the dual damascene process to a semiconductor substrate 11 including MOSFETs. The semiconductor device shown in FIG. 10 has four levels of wiring layers as with the semiconductor device shown in FIG. 1.

In each of insulating films 202 to 205, trenches for wiring layers and plugs are formed integrally. In each of these trenches in the insulating films, an wiring layers and a plugs are formed integrally as indicated at 206, 211, 216 and 221, and covered with a barrier metal, such as tantalum, indicated at 206-1, 211-1, 216-1 and 221-1. The multiple wiring layers are manufactured consecutively starting with the uppermost layer shown in FIG. 10.

In the state where the wiring layers formed as described above are bonded to a semiconductor substrate formed with MOSFETs, the top of each plug is covered with the barrier metal.

According to the third embodiment, using the dual damascene process, the uppermost wiring layer is formed first and the lowermost wiring layer is formed last. After that, the lowermost wiring layer is bonded to a semiconductor substrate formed with MOSFETs. As with the first and second embodiments using the single damascene process, therefore, mechanical and thermal stresses on the interlayer insulating films each consisting of a low-k film and narrow intermediate- and lower-level wiring layers can be relaxed.

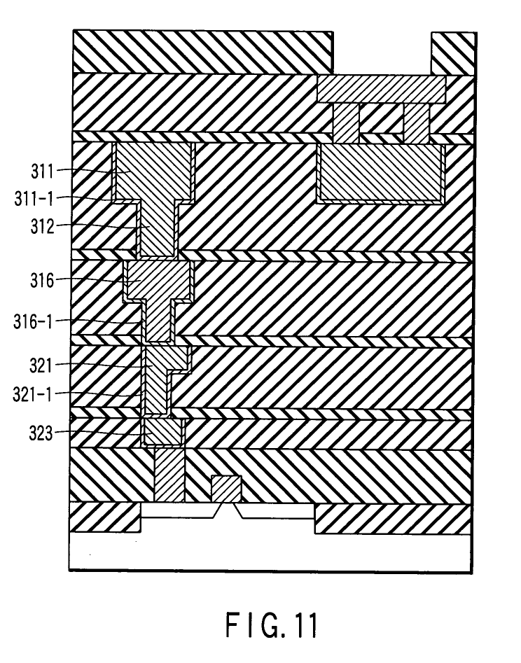

The simultaneous formation of an wiring layer and a plug using the dual damascene process can offer the following advantages. When a semiconductor device which is similar to the device of FIG. 10 is formed by the conventional method using a dual damascene process as shown in FIG. 11, for example, barrier metal 311-1 is formed on the bottoms and sides of an wiring layer 311 and an underlying via plug 312. Each wiring layer is made wider and thicker than the wiring layer below it. An wiring layer which is made wide and thick like the upper-level wiring layer has many vacancies in the Cu film which is its material. For this reason, the final heat treatment might cause Cu elements to move from the via plug 312 to the overlying wiring layer 311 and consequently cause voids to be produced in the plug. Likewise, voids might be produced in the plugs in the other wiring layers as well.

In contrast, in the case of the third embodiment, the barrier metal 211-1 fully covers the wiring layer 212 and the overlying via plug 211 in the finally formed semiconductor device as shown in FIG. 10. Since the barrier metal 211-1 is present between the via plug 211 and the overlying wiring layer 206, therefore, Cu elements will not move from the plug 211 to the overlying wiring layer 206 in the final heat treatment. Moreover, since the wiring layer 212 underlying the via plug 211 is narrower and thinner than the upper-level wiring layer 206, the wiring layer 212 has fewer vacancies than the wiring layer 206. For this reason, few Cu elements will move from the via plug 211 to the underlying wiring layer 212, thus preventing the production of voids in the via plug 211. For the same reason, the production of voids in the via plug in each of the other layers can be prevented.

Although the embodiments of the present invention have been described in terms of the formation of multilevel wiring layers and via plugs, this is not restrictive. It is also possible to form not only wiring layers but also functional elements such as capacitors in the multilevel wiring layer portion.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor element formed in a semiconductor substrate;
a plurality of insulating films stacked on the semiconductor substrate;
a plurality of wiring layers each of which is formed in a respective one of the insulating films; and
a barrier metal formed to continuously cover each of the wiring layers on the top and on both sides.

2. The device according to claim 1, further comprising plugs each of which is formed between the adjacent wiring layers, the plugs each being continuously covered with the barrier metal on the top and on both sides.

3. The device according to claim 1, further comprising plugs each of which is formed on the top of a respective one of the wiring layers, the corresponding wiring layer and plug being continuously formed with the barrier metal on the top and on both sides.

4. The device according to claim 1, wherein the insulating films include a first insulating film having a first dielectric constant, and a second insulating film having a dielectric constant higher than the first dielectric constant of the first insulating film, and the first insulating film is formed under the second insulating film.

5. A semiconductor device comprising:
a semiconductor element formed in a semiconductor substrate;
a plurality of insulating films stacked on the semiconductor substrate;
a plurality of wiring layers each of which is formed in a respective one of the insulating films;
a plurality of plugs each of which is formed in a respective one of the insulating films to connect the wiring layer formed in the corresponding insulating film and the wiring layer formed in another insulating film; and
a barrier metal formed to continuously cover the corresponding wiring layer and the plug on the corresponding wiring layer on the top and on both sides.

6. The device according to claim 5, wherein the corresponding wiring layer and the plug on the corresponding wiring layer are connected with each other with no barrier metal therebetween.

7. The device according to claim 5, wherein each of the plugs is connected to the top of the corresponding wiring layer.

8. A method of manufacturing a semiconductor device comprising:
forming an upper wiring layer on the surface of a first semiconductor substrate;
forming at least one lower wiring layer on the upper wiring layer; and
bonding the lower wiring layer formed on the first semiconductor substrate to a second semiconductor substrate including a semiconductor element.

9. The method according to claim 8, further comprising forming a plug connected to the upper wiring layer prior to the formation of the lower wiring layer.

10. The method according to claim 9, further comprising continuously covering the plug on the bottom and both sides with a barrier metal.

11. The method according to claim 8, further comprising, together with the upper wiring layer, forming a plug under the upper wiring layer so that they are connected together.

12. The method according to claim 11, further comprising continuously covering the upper wiring layer and the plug connected to the upper wiring layer on the bottom and both sides with a barrier metal.

13. A method of manufacturing a semiconductor device comprising:
forming a first insulating film having a first dielectric constant on the surface of a first semiconductor substrate;
forming an upper-level wiring layer in the first insulating film;
forming a second insulating film having a second dielectric constant lower than the first dielectric constant on the first insulating film;
forming at least one lower-level wiring layer in the second insulating film; and
bonding the lower-level wiring layer formed on the first semiconductor substrate to a second semiconductor substrate including a semiconductor element.

14. The method according to claim 13, further comprising forming a plug connected to the upper wiring layer prior to the formation of the lower wiring layer.

15. The method according to claim 14, further comprising continuously covering the plug on the bottom and both sides with a barrier metal.

16. The method according to claim 13, further comprising, together with the upper wiring layer, forming a plug under the upper wiring layer so that they are connected together.

17. The method according to claim 16, further comprising continuously covering the upper wiring layer and the plug connected to the upper wiring layer on the bottom and both sides with a barrier metal.

18. A method of manufacturing a semiconductor device comprising:
forming a first insulating film having a first dielectric constant on the surface of a first semiconductor substrate;
forming an upper-level wiring layer in the first insulating film;
forming a second insulating film having a second dielectric constant lower than the first dielectric constant on the surface of a second semiconductor substrate;
forming at least one lower-level wiring layer in the second insulating film;
bonding the lower-level wiring layer formed on the second semiconductor substrate to a third semiconductor substrate including a semiconductor element; and
bonding the first semiconductor substrate having the first insulating film and the upper-level wiring layer to the second insulating film after removal of the second semiconductor substrate.

19. The method according to claim 18, further comprising, together with at least one of the upper-level and the lower-level wiring layers, forming a plug under the one of the upper-level and the lower-level wiring layers so that they are connected together.

20. The method according to claim 19, further comprising continuously covering at least one of the upper-level and the lower-level wiring layers and the plug connected to the one of the upper-level and the lower-level wiring layers on the bottom and both sides with a barrier metal.
